(19) United States
(12) Patent Application Publication
(10) Pub. No.: US 2022/0346273 A1
(43) Pub. Date: Oct. 27, 2022

(54) SYSTEMS FOR COOLING ELECTRONIC COMPONENTS IN AN OUTDOOR COMPUTING SYSTEM

(71) Applicant: QUANTA COMPUTER INC., Taoyuan City (TW)

(72) Inventors: Yi-Chieh CHEN, Taoyuan City (TW); Yueh-Chang WU, Taoyuan City (TW); Te-Chuan WANG, Taoyuan City (TW)

(21) Appl. No.: 17/242,035

(22) Filed: Apr. 27, 2021

(51) Int. Cl. H05K 7/20; G06F 1/20; H05K 5/06

(52) U.S. Cl. CPC H05K 7/20309; G06F 1/20; H05K 5/061; H05K 7/20418

(57) ABSTRACT

A computing device comprises a heat sink including a base and a multi-dimensional thermal dissipation device disposed adjacent to the base. A thermally-conductive grease layer is disposed between and in direct contact with the multi-dimensional thermal dissipation device and the base. A gasket contains the thermally-conductive grease layer between the multi-dimensional thermal dissipation device and the base.

### FIELD OF THE INVENTION

The present invention relates generally to computing systems for telecommunications, and more specifically, to cooling electronic components in a sealed chassis for a telecommunications device.

### BACKGROUND OF THE INVENTION

Computing systems, such as those used for outdoor electronic telecommunications, require increasingly higher computing performance. Computing systems used in an outdoor environment need to be placed inside dustproof and waterproof housings to protect components from adverse environmental conditions. For outdoor electronic computing equipment, the housing for the computing systems typically acts as a heat sink for cooling the internal heat-generating electronic components. High-performance electronic components in computing systems, such as heat-generating components connected to high-performance expansion cards, cause increased heat generation within a computer chassis of such computing systems.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a computing system includes a heat sink including a base. A multi-dimensional thermal dissipation device is disposed adjacent to the base. A thermally-conductive grease layer is disposed between and in direct contact with the multi-dimensional thermal dissipation device and the base. A gasket contains the thermally-conductive grease layer between the multi-dimensional thermal dissipation device and the base.

In a further aspect of the implementation, the multi-dimensional thermal dissipation device includes a vapor chamber. In a further aspect, a base-facing planar surface of the multi-dimensional thermal dissipation device is a rough metal surface having an Ra between about 1.6 and about 6.3 such that the thermally-conductive grease layer minimizes air gaps between the rough metal surface and the base. In yet a further aspect, the multi-dimensional thermal dissipation device is mechanically secured to the base with one or more screws.

In a further aspect of the implementation, the gasket is embedded in a channel within the base. In a further aspect, the gasket extends along a perimeter of the vapor chamber. In yet a further aspect, the gasket is an elastic polymeric material. In yet a further aspect, the gasket is compressed to form a seal between the multi-dimensional thermal dissipation device and the base.

In a further aspect of the implementation, the heat sink includes a plurality of heat transfer fins protruding orthogonally to a planar surface of the multi-dimensional thermal dissipation device. In a further aspect, each of the plurality of heat transfer fins is secured by a corresponding interference fit with the base of the heat sink. In yet a further aspect, the plurality of heat transfer fins is oriented such that heat transferred to the heat sink rises out of air gaps between adjacently-spaced heat transfer fins. In yet a further aspect, a height of the plurality of heat transfer fins is greater than about five times a width of a gap between adjacently-spaced heat transfer fins. In a further aspect, one or more of the plurality of heat transfer fins include a channel filled with a refrigerant.

In a further aspect of the implementation, the computing system further comprises a sealed computer chassis housing defining an interior space and an exterior surface supporting the heat sink for dissipating heat from the interior space. In a further aspect, the computing system further comprises heat-generating components disposed within the interior space. The heat-generating components include one or more microprocessors and one or more memory devices. In a further aspect, at least one of the heat-generating components is disposed immediately adjacent to a planar surface of the multi-dimensional thermal dissipation device.

According to certain aspects of the present disclosure, a sealed server chassis includes a heat sink comprising a base and a plurality of heat transfer fins protruding from an exterior surface of the base. A vapor chamber is disposed adjacent to an interior surface of the base. A heat source is disposed immediately adjacent to the vapor chamber. A thermally-conductive grease layer is disposed between and in direct contact with the vapor chamber and the base. A gasket contains the thermally-conductive grease layer between the vapor chamber and the base.

In a further aspect of the implementation, the plurality of heat transfer fins protrude orthogonally from the exterior surface of the base.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The present disclosure, and its advantages, will be better understood from the following description of representative embodiments together with reference to the accompanying drawings. These drawings depict only representative embodiments, and are therefore not to be considered as limitations on the scope of the various embodiments or claims.

FIG. 1 is a perspective view of an exemplary sealed computer chassis housing for outdoor use including a heat sink, according to some implementations of the present disclosure.

FIG. 2 is an exemplary partial cross-sectional view through a sealed computer chassis for outdoor use including a heat sink, vapor chamber, and heat source, according to some implementations of the present disclosure.

FIG. 3 is an exemplary partial cross-sectional view through a sealed computer chassis for outdoor use including a heat sink and vapor chamber, according to some implementations of the present disclosure.

FIG. 4 is an exemplary cross-sectional view through a vapor chamber, according to some implementations of the present disclosure.

FIG. 5 is an exemplary side view of a vapor chamber connected to a heat sink of a computer chassis for outdoor use, according to some implementations of the present disclosure.

FIG. 6 is an exemplary side perspective view of a computer chassis for outdoor use, including a heat sink with heat transfer fins, according to some implementations of the present disclosure.

### DETAILED DESCRIPTION

An outdoor computing system is described that includes a heat sink, a multi-dimensional thermal dissipation device (e.g., a vapor chamber), a thermally-conductive grease layer, and a gasket. The thermal dissipation device is disposed adjacent to a base of the heat sink. The multi-dimensional thermally-conductive grease layer is disposed between the multi-dimensional thermal dissipation device and the base. The gasket contains the thermally-conductive grease layer between the multi-dimensional thermal dissipation device and the base. The multi-dimensional thermal dissipation device is configured for at least two-dimensional thermal conduction to rapidly transfer heat from the heat source (e.g., a central processing unit) to a cooling area.

The described outdoor computing system has applications in fifth-generation wireless mobile communications technology (5G). With the increased transmission speeds of 5G over earlier generation technologies, power consumption of 5G computing systems has likewise increased. The increased power consumption in turn results in increased heat generation. If the computing system does not have sufficient heat dissipation, the operating efficiency of the computing system is reduced and equipment problems can result, such as damage to the computing components, system crashes, and disconnection of the network that degrades the user experience.

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

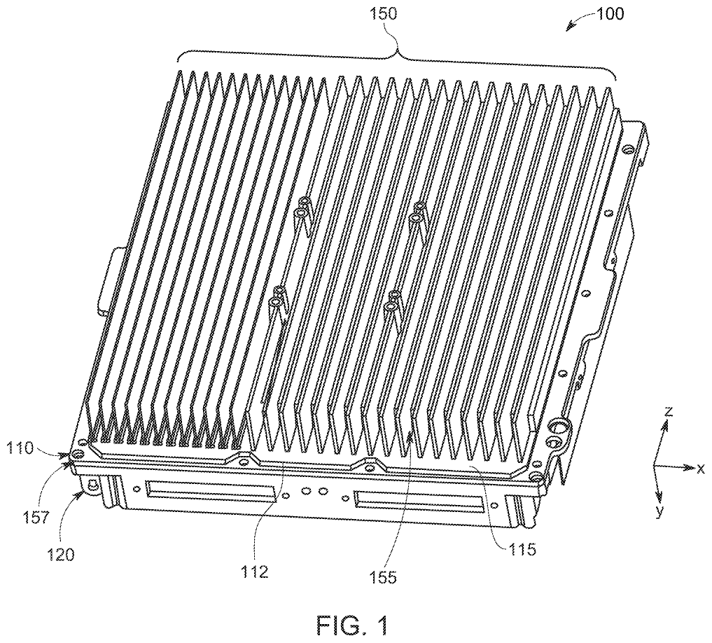

Referring now to FIG. 1, a perspective view of an exemplary computer chassis housing 100, such as for a computing system or a server system, is depicted. The computer chassis housing 100 is sealed for outdoor use and includes an exterior surface 115 and an interior space (not shown). A plurality of heat transfer fins 150 is disposed on the exterior surface 115 and acts as a heat sink. The computer chassis housing 100 includes at least two housing enclosure components 110, 120 that are secured together to form a dustproof and waterproof interface 157 generally along the x-z plane between the two housing enclosure components 110, 120. The computer chassis housing 100 protects electronic components, including heat-generating components, disposed within the interior space of the computer chassis housing 100.

The plurality of heat transfer fins 150 are spaced along the exterior surface 115 of a base 112 of the housing enclosure component 110. The exterior surface 115 is generally parallel to the x-z plane. The plurality of heat transfer fins 150 protrude orthogonally from the exterior surface 115 such that the plurality of heat transfer fins 150 are generally parallel to the y-z plane. The plurality of heat transfer fins 150 and the base 112 together form a heat sink. The heat transfer fins 150 may be secured via an interference fit, or other mechanical fastening system, with the base 112.

In some implementations, a second plurality of heat transfer fins (not shown) may similarly be positioned on an opposite exterior surface (not shown) associated with the housing enclosure component 120. During operation of electronic components within the computer chassis housing 100, ambient air will be heated at one or both exterior surfaces (e.g., exterior surface 115) of the computer chassis housing 100 and flow through air gaps (e.g., gap 155) between adjacent heat transfer fins. Natural convection due to the pressure differential between the heated ambient air in the gaps 155 and the surrounding ambient air will drive the heated air upwards and away from the exterior surface 115. In some implementations, a height of the plurality of heat transfer fins 150 orthogonal to the exterior surface 115 is greater than about five times a width of the air gap between adjacently-spaced heat transfer fins 150. In some implementations, the plurality of heat transfer fins 150 are the same height. In some implementations, the majority of the plurality of heat transfer fins 150 are the same height. In some implementations, the computer chassis housing 100 has a width along the x-axis of approximately six to seven inches or greater, which allows a sufficient number of heat transfer fins 150 to be placed on the exterior surface 115 of the housing enclosure component 110 to meet the heat dissipation demands of heat-generating electronic components (not shown) disposed within the computer chassis housing 100.

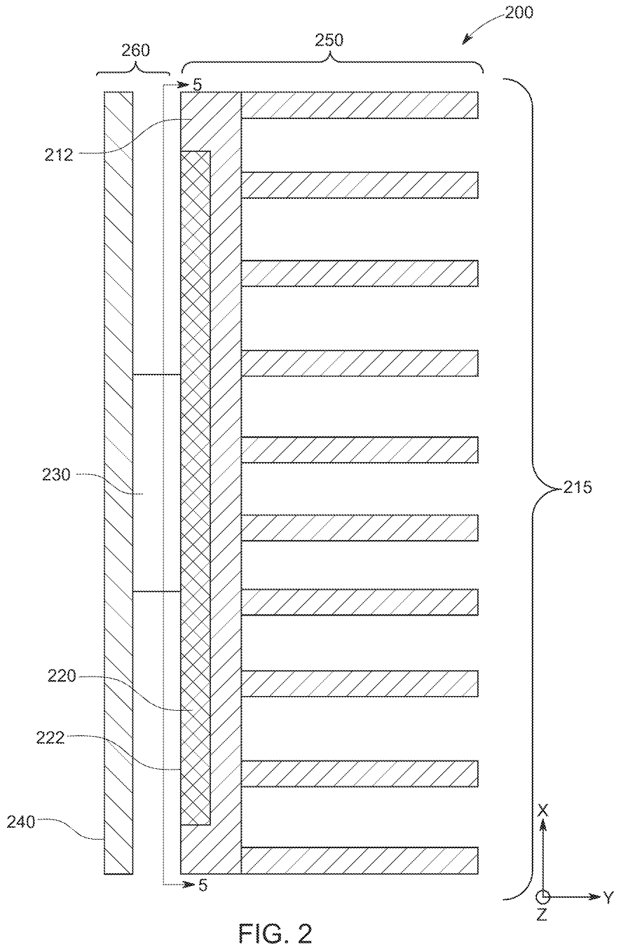

Referring to FIG. 2, a schematic cross-sectional view through a portion of a sealed computer chassis for outdoor use is depicted. The schematic in FIG. 2 aligns approximately with the exemplary x-y plane of the computer chassis housing 100 in FIG. 1. The schematic includes a heat sink 200 for transferring heat from an interior space 260 of the sealed computer chassis. In some implementations, the heat sink 200 includes a base 212 and heat transfer fins 215 disposed in an exterior space 250 surrounding the sealed computer chassis. A multi-dimensional thermal dissipation device 220, such as a vapor chamber, is disposed adjacent to the base 212 of the heat sink 200. In some aspects, the multi-dimensional thermal dissipation device 220 may be embedded in the base 212. In addition, a heat source 230 is depicted that may comprise one or more targeted heat-generating components, such as one or more microprocessors and/or memory devices, disposed on a main board 240, where all the heat-generating components are disposed within the interior space 260 of the sealed computer chassis. The heat transfer fins 215 of the heat sink 200 protrude orthogonally to a planar surface 222 of the multi-dimensional thermal dissipation device 220.

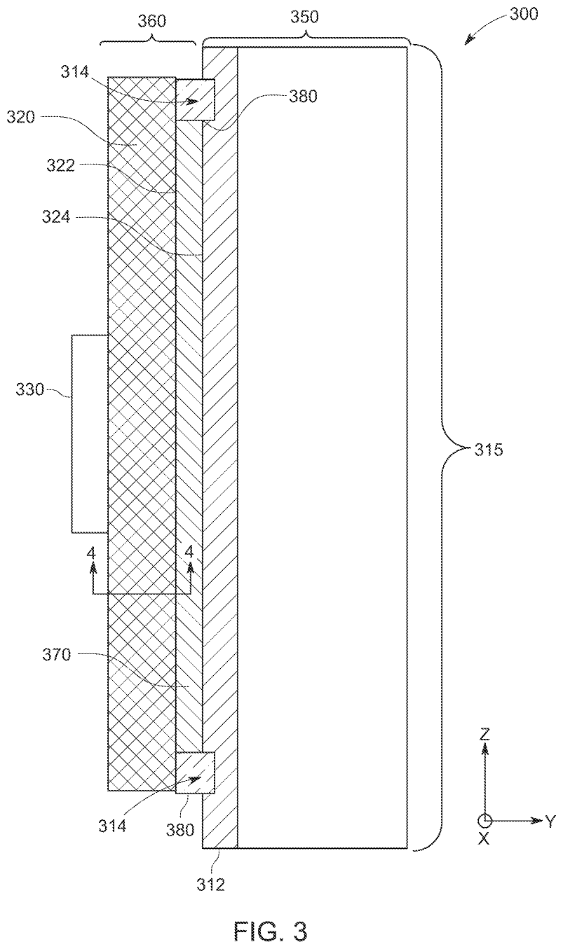

Referring to FIG. 3, another partial schematic cross-sectional view through a sealed computer chassis for outdoor use is depicted. The schematic in FIG. 3 aligns approximately with the exemplary y-z plane of the computer chassis housing 100 in FIG. 1. Similar to FIG. 2, the depicted schematic of the portion of the sealed computer chassis includes a heat sink 300 for transferring heat from an interior space 360 of the sealed computer chassis. In some implementations, the heat sink 300 includes a base 312 and heat transfer fins 315 disposed in an exterior space 350 surrounding the sealed computer chassis. While only one heat transfer fin is depicted in FIG. 3, the heat transfer fins 315 are arranged adjacent to each other, similar to the plurality of heat transfer fins 150, 215 in FIGS. 1 and 2. A vapor chamber 320 is disposed adjacent to the base 312 of the heat sink 300, as generally depicted in FIG. 3. Similar to the depiction in FIG. 2, in some aspects, the vapor chamber 320 may be embedded in the base 312. In addition, a heat source 330 is depicted that may include one or more targeted heat-generating components, such as one or more microprocessors and/or memory devices, disposed on a main board (not shown), where all the heat-generating components are disposed within an interior space 360 of the sealed computer chassis. The heat transfer fins 315 of the heat sink 300 protrude orthogonally to a planar surface 322 of the vapor chamber 320.

A thermally-conductive grease layer 370 is disposed between and in direct contact with the vapor chamber 320 and the base 312. A gasket 380 further contains the thermally-conductive grease layer 370 between the vapor chamber 320 and the base 312 of the heat sink. 300. A base-facing planar surface 322 of the vapor chamber 320 can be a rough metal surface with the presence of air gap when placed in direct contact with the interior surface 324 of the base 312. In some implementations, the rough metal surface of the vapor chamber 320 has an Ra between about 1.6 and 6.3. The presence of the air gap allows for there to be an imperfect thermal connection between the vapor chamber 320 and the heat sink 300, when the two components are in direct contact with each other. The thermally-conductive grease layer 370 minimizes air gaps between the rough metal surface of the vapor chamber 320 and the base 312, allowing for an efficient heat transfer from the vapor chamber 320 to the heat sink 300. The thickness of the grease layer 370 can vary. In some implementations, the thickness of the grease layer 370 is large enough to smoothen the imperfections in the rough metal surface and minimize any air gaps between the vapor chamber 320 and the heat sink 300.

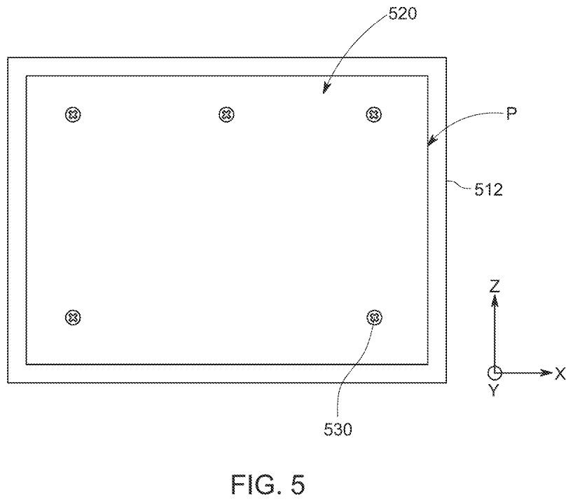

In some implementations, the gasket 380 can be embedded in a channel 314 within the base 312. In some aspects, the gasket 380 and/or the channel 314 extend along an approximate perimeter P (see FIG. 5) of the vapor chamber 320. The gasket 380 can be an elastic polymeric material or other compressible material that can create a seal when compressed to contain the thermally-conductive grease layer 370. For example, the gasket 380 may compress as the vapor chamber 320 is compressed against the base 312 to allow containment of the thermally-conductive grease layer 370 such that the grease will remain in place flowing out from between the vapor chamber 320 and the base 312. In some implementations, a sealed computer chassis for outdoor use includes a multi-dimensional thermal dissipation device, heat sink, and thermally-conductive grease layer. The sealed computer chassis has dimensions of about 12 to 18 inches in length by about 14 to 20 inches in width by about 4 to 10 inches in depth and is able to dissipate approximately 250 to 325 Watts of heat.

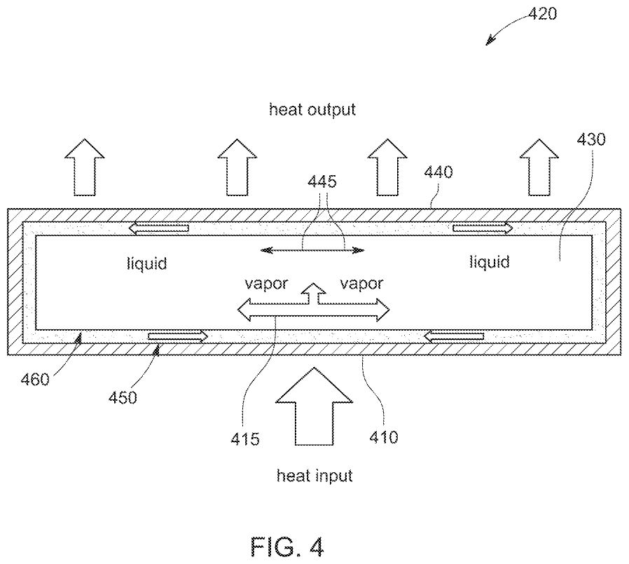

Referring to FIG. 4, a schematic cross-sectional view through the vapor chamber from FIG. 3 is depicted. The vapor chamber 420 is a planar heat pipe that spreads the heat along two dimensions. The vapor chamber 420 includes a working fluid (e.g., water) that vaporizes in a vaporizing compartment 430 and travels to cooler areas of the vapor chamber 420 adjacent to a heat output surface 440, where the working fluid condenses back to a liquid phase. The vapor chamber 420 is in thermal contact with a heat-generating source (not shown), such as a microprocessor or memory device, that provides a heat input to the vapor chamber at a heat input surface 410.

The vapor chamber 420 includes a shell 450 having a heat output surface 440 and a heat input surface 410. The shell 450 is made from a heat-conductive material, such as a metal (e.g., copper), that readily receives the heat input at the heat input surface 410. A wick 460 acts as a conduit that carries condensed working liquid (e.g., water) from a heat output side 445 of the vapor chamber 420 back to the heat input side 415, where the received heat input causes the liquid to vaporize. The vaporized liquid then moves back toward the heat output side 445 of the vapor chamber 420 and condenses where the working liquid is reabsorbed by the wick 460 and again carried back to the heat input side 415.

The heat output surface 440 of the vapor chamber 420 is in direct contact with a thermally-conductive grease layer, such as the thermally-conductive grease layer 370 described in FIG. 3, that transfers the output heat to a heat sink, such as the heat sinks 200, 300 described for FIGS. 2 and 3. The steps of vaporization and condensation forms a repetitive cycle of heat transfer from the heat-generating electronic components thermally connected to the heat input surface 410 to the heat sink thermally connected to the heat output surface 440.

FIG. 5 is an exemplary cross-sectional view of a multi-dimensional thermal dissipation device 520, such as a vapor chamber, connected to a base 512 of a heat sink of a computer chassis housing for outdoor use. The schematic in FIG. 5 aligns approximately with the exemplary x-z plane of the computer chassis housing 100 in FIG. 1. In some implementations, the multi-dimensional thermal dissipation device 520 is mechanically secured to the base 512, such as with one or more mechanical fasteners 530 (e.g., screws). Mechanical fastening of the multi-dimensional thermal dissipation device 520 is desirable. Such fastening contains thermally-induced strains due to temperature fluctuations that could otherwise cause separation or a loosening of the multi-dimensional thermal dissipation device 520 from the base 512 of the heat sink, which would degrade the effectiveness of heat dissipation.

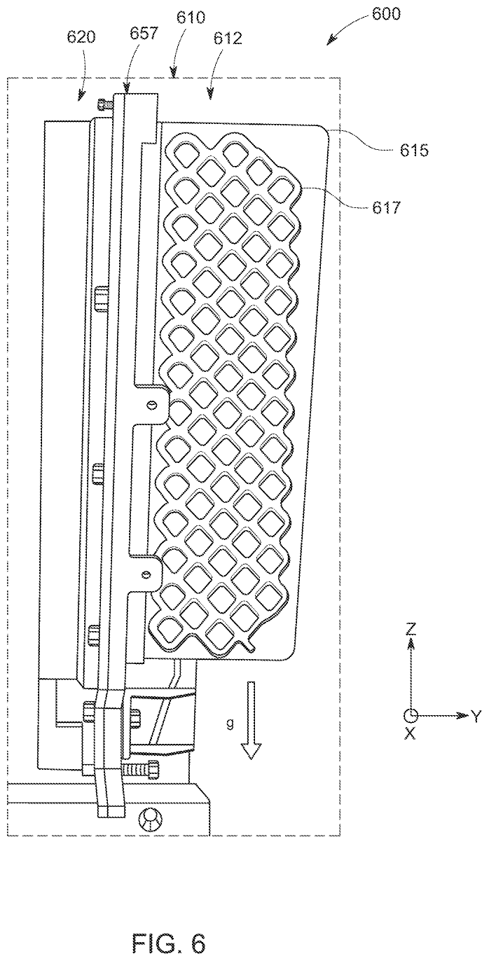

FIG. 6 is an exemplary side perspective view of a computer chassis housing 600 for outdoor use, including a heat sink 612 with heat transfer fins 615. The view presented in FIG. 5 aligns approximately with the exemplary y-z plane of the computer chassis housing 100, 300 in FIGS. 1 and 3. The heat transfer fins 615 include channels 617 filled with a refrigerant. While only one heat transfer fin is depicted in FIG. 6, the heat transfer fins 615 are arranged adjacent to each other, similar to the plurality of heat transfer fins 150, 215 in FIGS. 1 and 2.

The computer chassis housing 600 is sealed for outdoor use and includes an interior space (not shown). Similar to the computer chassis housing 100 in FIG. 1, the computer chassis housing 600 can include two housing enclosure components 610, 620 that are secured together to form a dustproof and waterproof interface 657 generally along the x-z plane between the two housing enclosure components 610, 620. The computer chassis housing 600 protects electronic components, including heat-generating components, disposed within the interior space.

In some implementations, the heat transfer fins 615 are formed by two plates of aluminum material having channels stamped therein with the plates subsequently roll-bonded together. An exemplary refrigerant for filling the channels 617 can include an R1233zd refrigerant or similar material.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should he defined in accordance with the following claims and their equivalents.

What is claimed is:

1. A computing system comprising:
a heat sink including a base;
a multi-dimensional thermal dissipation device disposed adjacent to the base;
a thermally-conductive grease layer disposed between and in direct contact with the multi-dimensional thermal dissipation device and the base; and
a gasket for containing the thermally-conductive grease layer between the multi-dimensional thermal dissipation device and the base.

2. The computing system of claim 1, wherein the multi-dimensional thermal dissipation device includes a vapor chamber.

3. The computing system of claim 1, wherein a base-facing planar surface of the multi-dimensional thermal dissipation device is a rough metal surface having an Ra between about 1.6 and about 6.3 such that the theitnally-conductive grease layer minimizes air gaps between the rough metal surface and the base.

4. The computing system of claim 1, wherein the multi-dimensional thermal dissipation device is mechanically secured to the base with one or more screws.

5. The computing system of claim 1, wherein the gasket is embedded in a channel within the base.

6. The computing system of claim 1, wherein the gasket extends along a perimeter of the vapor chamber.

7. The computing system of claim 1, wherein the gasket is an elastic polymeric material.

8. The computing system of claim 1, wherein the gasket is compressed to form a seal between the multi-dimensional thermal dissipation device and the base.

9. The computing system of claim 1, wherein the heat sink includes a plurality of heat transfer fins protruding orthogonally to a planar surface of the multi-dimensional thermal dissipation device.

10. The computing system of claim 9, wherein each of the plurality of heat transfer fins is secured by a corresponding interference fit with the base of the heat sink.

11. The computing system of claim 9, wherein the plurality of heat transfer fins is oriented such that heat transferred to the heat sink rises out of air gaps between adjacently-spaced heat transfer fins.

12. The computing system of claim 9, wherein a height of the plurality of heat transfer fins is greater than about five times a width of a gap between adjacently-spaced heat transfer fins.

13. The computing system of claim 9, wherein one or more of the plurality of heat transfer fins include a channel filled with a refrigerant.

14. The computing system of claim 1, further comprising a sealed computer chassis housing defining an interior space and an exterior surface supporting the heat sink for dissipating heat from the interior space.

15. The computing system of claim 14, further comprising heat-generating components disposed within the interior space, the heat-generating components including one or more microprocessors and one or more memory devices.

16. The computing system of claim 15, wherein at least one of the heat-generating components is disposed immediately adjacent to a planar surface of the multi-dimensional thermal dissipation device.

17. A sealed server chassis comprising:
a heat sink comprising a base and a plurality of heat transfer fins protruding from an exterior surface of the base;
a vapor chamber disposed adjacent to an interior surface of the base;
a heat source disposed immediately adjacent to the vapor chamber;
a thermally-conductive grease layer disposed between and in direct contact with the vapor chamber and the base; and
a gasket for containing the thermally-conductive grease layer between the vapor chamber and the base.

18. The sealed server chassis of claim 17, wherein the plurality of heat transfer fins protrude orthogonally from the exterior surface of the base.
